(19) United States
(12) Patent Application Publication
(10) Pub. No.: US 2024/0194564 A1
(43) Pub. Date: Jun. 13, 2024

(54) FLUIDIC-CHANNEL COOLED SUBSTRATES

(71) Applicant: SEMICONDUCTOR COMPONENTS INDUSTRIES, LLC, Scottsdale, AZ (US)

(72) Inventors: Jihwan KIM, Seoul (KR); Oseob JEON, Seoul (KR); Seungwon IM, Bucheon (KR); Dongwook KANG, Bucheon (KR)

(73) Assignee: SEMICONDUCTOR COMPONENTS INDUSTRIES, LLC, Scottsdale, AZ (US)

(21) Appl. No.: 18/444,251

(22) Filed: Feb. 16, 2024

Related U.S. Application Data
(63) Continuation-in-part of application No. 18/491,369, filed on Oct. 20, 2023.
(60) Provisional application No. 63/380,460, filed on Oct. 21, 2022.

(51) Int. Cl. H01L 23/473; H01L 23/15; H01L 23/31; H01L 25/065

(52) U.S. Cl. CPC H01L 23/473; H01L 23/15; H01L 23/3121; H01L 25/0652

(57) ABSTRACT

In a general aspect, a semiconductor device module includes a ceramic substrate having a first surface and a second surface opposite the first surface, a patterned metal layer disposed on the first surface of the ceramic substrate, a semiconductor die disposed on the patterned metal layer, and a cooling structure disposed on the second surface of the ceramic substrate. The cooling structure includes a plurality of copper sheets defining a plurality of fluidic-cooling channels. At least one copper sheet of the plurality of copper sheets is at least one of coated or plated with a corrosion-resistant material. The module also includes a molding compound that encapsulates the ceramic substrate, the patterned metal layer and the semiconductor die. The molding compound also partially encapsulates the cooling structure, such that a fluidic interface surface of the cooling structure is exposed through the molding compound.

### RELATED APPLICATION

This application is a continuation-in-part application of U.S. application Ser. No. 18/491,369, filed on Oct. 20, 2023, entitled “MOLDED POWER MODULES WITH FLUIDIC-CHANNEL COOLED SUBSTRATES,” which claims priority to and the benefit of U.S. Provisional Application No. 63/380,460, filed on Oct. 21, 2022, entitled “TRANSFER MOLDED POWER MODULE PACKAGE,” the disclosures of which are incorporated by reference herein in their entireties.

### TECHNICAL FIELD

This description relates to electronic device assemblies. More specifically, this description relates to semiconductor device modules, such as power semiconductor device modules, and associated electronic device assemblies.

### BACKGROUND

Molded semiconductor device modules, such as transfer-molded power semiconductor modules and associated electronic device assemblies and systems can be used in a number of different application, such as automotive applications, industrial applications, consumer electronics application, among others. For instance, such semiconductor device modules can be used in power-inverters, such as for electric vehicles and/or hybrid electric vehicles, as an example.

Product cost, performance and reliability are often competing considerations in the design, development and production of such semiconductor device modules. For instance product size, and associated cost, can be affected by thermal performance requirements of a given application. For instance, in order to achieve a desired thermal resistance (Rₜₕ) opportunities for reducing device size and/or or reducing material costs can be limited. Further, current approaches for implementing thermal dissipation mechanism can include the use of thermal interface materials, such as thermal grease, which can affect thermal dissipation efficiency.

### SUMMARY

In a general aspect, a semiconductor device module includes a ceramic substrate having a first surface and a second surface opposite the first surface, a patterned metal layer disposed on the first surface of the ceramic substrate, a semiconductor die disposed on the patterned metal layer, and a cooling structure disposed on the second surface of the ceramic substrate. The cooling structure includes a plurality of copper sheets defining a plurality of fluidic-cooling channels. At least one copper sheet of the plurality of copper sheets is at least one of coated or plated with a corrosion-resistant material. The module also includes a molding compound that encapsulates the ceramic substrate, the patterned metal layer and the semiconductor die. The molding compound also partially encapsulates the cooling structure, such that a fluidic interface surface of the cooling structure is exposed through the molding compound.

In another general aspect, an electronic device assembly includes a molded semiconductor device module. The assembly includes a ceramic substrate having a first surface and a second surface opposite the first surface, a patterned metal layer disposed on the first surface of the ceramic substrate, a semiconductor die disposed on the patterned metal layer, and a cooling structure disposed on the second surface of the ceramic substrate. The cooling structure includes a plurality of fluidic-cooling channels, and a molding compound. The molding compound encapsulates the ceramic substrate, the patterned metal layer and the semiconductor die. The molding compound also partially encapsulates the cooling structure, such that a fluidic interface surface of the cooling structure is exposed through the molding compound. The assembly also includes a coolant distributor coupled with the fluidic interface surface of the cooling structure, and a fluidic-cooling jacket. The fluidic-cooling jacket includes a coolant inlet, a first fluidic circuit configured to provide a first portion of a coolant flow received at the coolant inlet to the coolant distributor, a second fluidic circuit configured such that a second portion of the coolant flow bypasses the coolant distributor, and a coolant outlet configured to receive the first portion of the coolant flow and the second portion of the coolant flow for egress from the fluidic-cooling jacket.

### BRIEF DESCRIPTION OF THE DRAWINGS

FIGS. 1A and 1B are diagrams schematically illustrating respective examples of electronic device assemblies including molded power modules with fluidic-channel cooled substrates.

FIG. 2 is a diagram schematically illustrating coolant flow in an example electronic device assembly including molded power modules with fluidic-channel cooled substrates.

FIGS. 3A through 3C are diagrams illustrating coolant flow in an example implementation of the electronic device assembly of FIG. 2.

FIGS. 4A through 4C are diagrams illustrating aspects of an example power module substrate with a fluidic-channel cooled substrate.

FIGS. 5A through 5D are diagrams illustrating example layers of a fluidic-channel cooled substrate, such as the substrate of FIGS. 4A through 4C.

FIG. 6 is a diagram illustrating an example semiconductor device module including a fluidic-channel cooled substrate and coolant distributor.

FIG. 7 is a diagram illustrating a cut-way view of an example electronic device assembly including dual-sided fluidic-channel cooled substrates, coolant distributors, and a fluidic coolant jacket.

FIG. 8 is a diagram illustrating a magnified view of a portion of the electronic device assembly of FIG. 7.

FIGS. 9A through 9C are diagrams illustrating an example molded power module with dual-sided, fluidic-channel cooling.

FIGS. 10A through 10C are diagrams illustrating an example molded power module with single-sided, fluidic-channel cooling.

FIG. 11A is a diagram illustrating an example electronic device assembly.

FIGS. 11B and 11C are diagrams schematically illustrating cross-sectional view of implementations of the electronic device assembly of FIG. 11A.

FIGS. 12A through 12C are diagrams illustrating an example fluidic cooling jacket.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

In prior implementations of semiconductor device modules and associated assemblies and systems, achieving a desired thermal resistance (Rₜₕ) for a given device configuration can establish a size of a thermal dissipation mechanism used, such as fin pin cooling plate or a heat sink. For instance, to achieve a desired Rₜₕ, a cooling plate or heat sink with a sufficient thermal mass for achieving that Rₜₕ may be used, where the size of the cooling plate or heat sink can be a limiting factor for reducing a package size of an associated module. This limitation can be further compounded by a thermal interface material used between a molded semiconductor device module package and the cooling plate or heat sink. Accordingly, opportunities to reduce module size and associated material costs can be limited by thermal dissipation requirements. As thermal dissipation requirements directly relate to device electrical performance and semiconductor device module reliability, adhering to such requirements is important for proper semiconductor device module operation and lifetime.

The example implementations described herein can overcome at least some of the foregoing described drawbacks. For instance, in described implementations, a molded semiconductor device power module can include at least one cooling structure with a plurality of fluidic-cooling channels, which can also be referred to as micro-cooling channels, micro-channels and/or cooling channels. Such cooling structures can be integrated in a molding compound of an associated semiconductor device module, and can be directly coupled to a ceramic substrate of the module. That is, such a cooling structure can be brazed or sintered to a surface of a ceramic substrate of a module, to produce a fluidic-channel cooled substrate, while a patterned metal layer and one or more semiconductor die can be included on an opposite surface of the ceramic substrate.

In some implementations, such as examples described herein, multiple ceramic substrates with attached fluidic-channel cooling structures (fluidic-channel cooled substrates) can be included in a semiconductor device power module, for example, one fluidic-channel cooled substrate can be coupled with each primary surface of a semiconductor die, or plurality of semiconductor die included in the module.

Such approaches eliminate use of thermal interface materials and associated drawbacks. Also, the approaches described herein can achieve a twenty-five percent or greater reduction in Rₜₕ over a comparably sized cooling plate or heat sink. Accordingly, for a given semiconductor device power module, the approaches described herein can facilitate reductions of package size with lower and or equivalent Rₜₕ as compared with prior approaches.

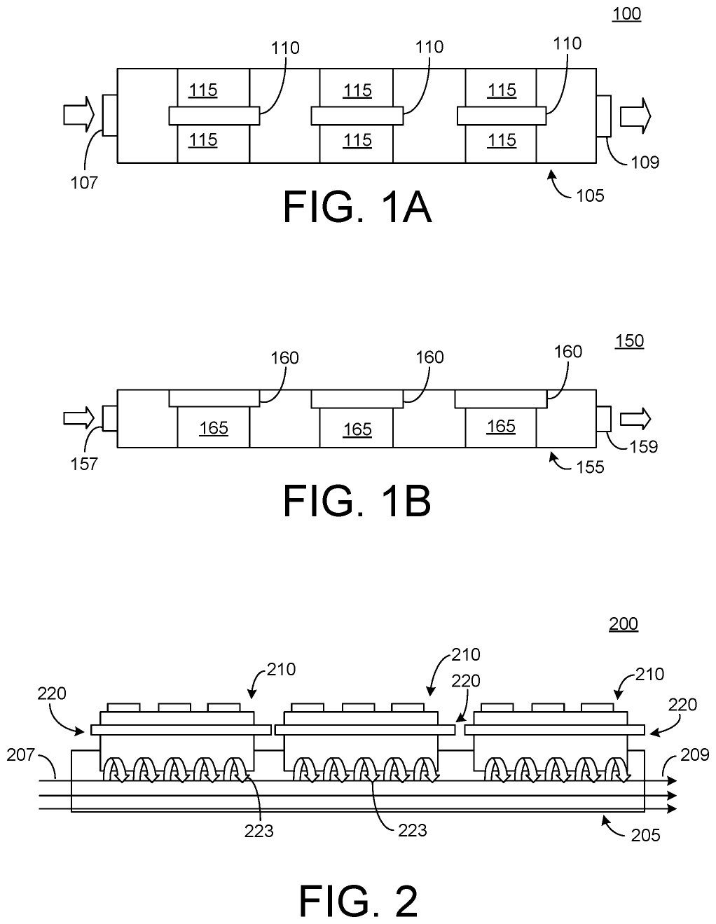

FIGS. 1A and 1B are diagrams schematically illustrating respective examples of an electronic device assembly 100 and an electronic device assembly 150. In example implementations, the electronic device assembly 100 and the electronic device assembly 150 include transfer molded power modules with fluidic-channel cooled substrates, such as those described herein. As shown in FIG. 1A, the electronic device assembly 100 includes a cooling jacket 105, which can also be referred to as a water jacket, a fluid jacket, and/or a jacket. The electronic device assembly 100 also includes semiconductor device power modules 110 that can each include two integrated fluidic-cooled substrates. That is, the power modules 110 can be referred to as being dual-sided cooled modules. The electronic device assembly 100 also includes coolant distributors 115, where a coolant distributor 115 is respectively coupled with each fluidic-channel cooled substrate. As shown in FIG. 1A, the power modules 110 and their associated coolant distributors 115 can be fluidically sealed in the cooling jacket 105.

In this example, a coolant flow can be received at an inlet port 107 of the cooling jacket 105. The coolant flow can generally proceed left to right in FIG. 1A, for example, from the inlet port 107 to an outlet port 109. However, when the coolant flow reaches the left-most power module 110 and associated coolant distributors 115, the coolant distributors 115 can route, or distribute the coolant flow into the fluidic-channel cooled substrates of the power modules 110. After flowing through the fluidic-channel cooled substrates, the coolant flow can egress from the coolant distributors 115 of the left-most power module 110, and proceed to the middle power module 110 and its coolant distributors 115, which route the coolant flow into the fluidic-channel cooled substrates of the middle power module 110. After egress from the coolant distributors 115 of the middle power modules 110, the coolant flow can proceed to the right-most power module 110 and its coolant distributors 115, and then after flowing through the associated fluidic-channel cooled substrates, the coolant flow can proceed out of the cooling jacket 105 v via the outlet port 109.

As shown in FIG. 1B, the electronic device assembly 150 includes similar aspects as the electronic device assembly 100. For instance, the electronic device assembly 150 includes a cooling jacket, with in inlet port 157 and an outlet port 159. The electronic device assembly 150 further includes semiconductor device power modules 160 that each include an integrated fluidic-cooled substrate. That is, the power modules 160 can be referred to as being single-sided cooled modules. The electronic device assembly 150 also includes coolant distributors 165, where a coolant distributor 115 is respectively coupled with each fluidic-channel cooled substrate. As shown in FIG. 1B, as with the power modules 110 and the coolant distributors 115 of the electronic device assembly 100, the power modules 160 and their associated coolant distributors 165 can be fluidically sealed in the cooling jacket 155. Coolant flow can occur similarly in the electronic device assembly 150 as in the electronic device assembly 100, with exception that for each semiconductor device power modules 160, the coolant flow is distributed to, by a corresponding coolant distributors 165, and flow through a single fluidic-channel cooled substrate.

FIG. 2 is a diagram schematically illustrating coolant flow in an example electronic device assembly 200 including power modules 210 with fluidic-channel cooled substrates 220. As shown in FIG. 2, in the electronic device assembly 200, a coolant flow, which is indicated by left to right arrows, generally proceeds from an inlet port 207 to an outlet port 209 of a cooling jacket 205. As the coolant flows from the inlet port 207 to the outlet port 209, coolant distributors (not specifically shown in FIG. 2) can route the coolant flow into fluidic-channels of the fluidic-channel cooled substrates 220 of the molded power modules 210.

As shown by arrows 223 in FIG. 2, coolant flow in the fluidic-channel cooled substrates 220 can, in the view of FIG. 2, proceed upward from the cooling jacket 205, for example, via a coolant distributor. The coolant flow in a given fluidic-channel can then reverse direction in the fluidic-channel cooled substrates 220, and the proceed downward back into the cooling jacket 205 via the distributor, where it can then proceed to next molded power module 210, or to the outlet port 209 of the cooling jacket 205 if egress the right-most molded power module 210. Accordingly, each fluidic-channel of the fluidic-channel cooled substrates 220 can have an inlet portion (upward flow), an outlet portion (downward flow), and a U-turn portion (flow between the inlet portion and the outlet portion). That is, the inlet portion and the outlet portion can be in fluidic communication with a coolant distributor, and/or the cooling jacket 205, and the U-turn portion can fluidically couple the inlet portion with the outlet portion.

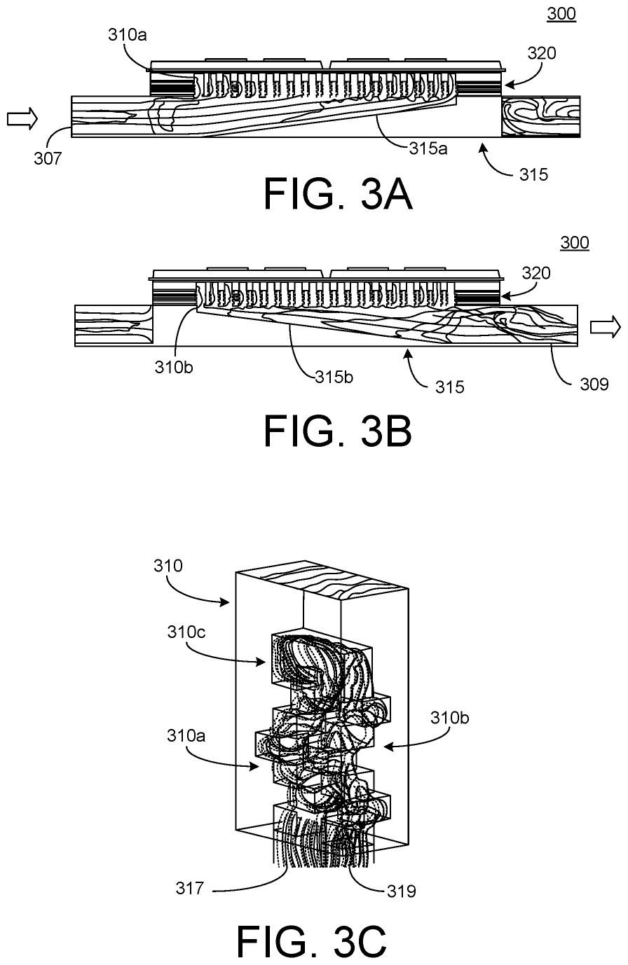

FIGS. 3A through 3C are diagrams illustrating coolant flow in an example implementation of the electronic device assembly of FIG. 2. Specifically, FIG. 3A illustrates coolant flow into an electronic device assembly 300, which can implement the single-sided cooling arrangement of FIG. 2. FIG. 3B illustrates coolant flow out of the electronic device assembly 300, and FIG. 3C illustrates coolant flow in a fluidic-channel 310 of a fluidic-channel cooling structure 320 of the electronic device assembly 300. In this example, coolant ingresses, or flows into the electronic device assembly 300 via an inlet port 307, then flows, via a coolant distributor 315, into the fluidic-channels 310 of the fluidic-channel cooling structure 320. Also in this example, coolant egresses, or flow out of the electronic device assembly 300 via an outlet port 309 after flowing from the fluidic-channels 310 of the fluidic-channel cooling structure 320 to the coolant distributor 315 and then to the outlet port 309.

As shown in FIG. 3C, a fluidic-channel of the fluidic-channels 310 can include an inlet portion 310a, an outlet portion 310b, and a U-turn portion 310c, where the U-turn portion 310c fluidically couples the inlet portion 310a with the outlet portion 310b. As shown in FIG. 3C, coolant enters the fluidic-channel 310 from an inlet channel 315a of the coolant distributor 315 via ingress 317, and exits the fluidic-channel 310 via egress 319 to an outlet channel 315b of the coolant distributor 315. In some implementations, the ingress 317 and the egress 319 can be included in a fluidic interface surface of a fluidic-channel cooling structure 32, such as the fluidic-channel cooling structure 320. As shown in FIG. 3C, the inlet portion 310a and the outlet portion 310b can be configured to cause a turbulent flow of coolant in the fluidic-channel 310, which can improve thermal dissipation efficiency of the fluidic-channel cooling structure 320, such as by increasing an amount of heat transfer as compared to a non-turbulent current flow. Accordingly, such approaches can contribute to reducing Rₜₕ of an associated electronic device assembly, such as in the examples described herein.

In this example, the inlet channel 315a and the outlet channel 315b are shown as being ramped with opposite slopes. Such an arrangement can help control a flow of coolant in the coolant distributor 315 and in the fluidic-channels 310 of the fluidic-channel cooling structure 320. In some implementations, other features can be used for flow control, such as fins, blades, and/or combinations of such features. The particular arrangement and configuration of inlet channels and outlet channels of a coolant distributor will depend on the particular implementation.

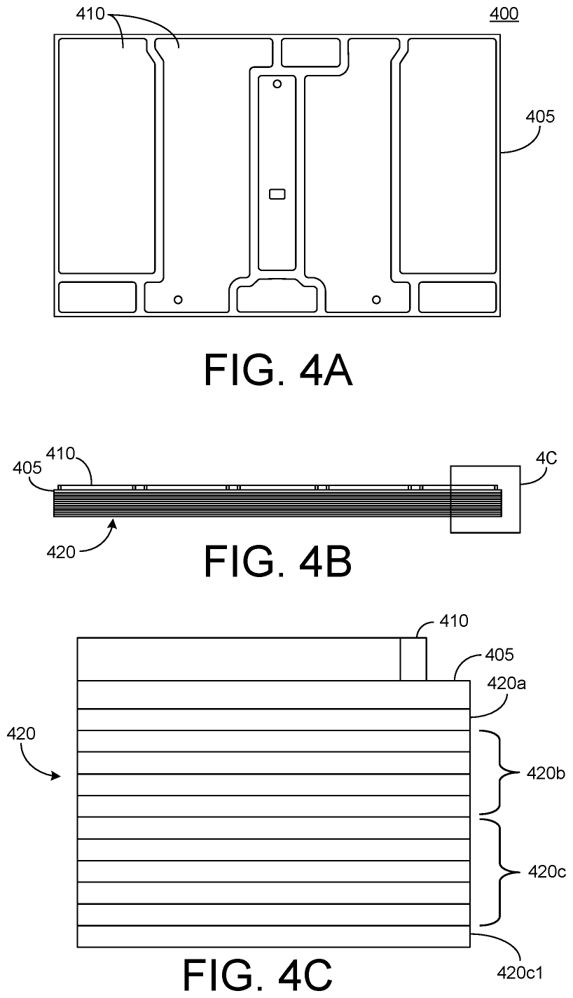

FIGS. 4A through 4C are diagrams illustrating aspects of an example fluidic-channel cooled substrate 400 that can be used to implement a semiconductor device power module. FIG. 4A is a top-down, or plan view of the fluidic-channel cooled substrate 400, FIG. 4B is a side view of the fluidic-channel cooled substrate 400, and FIG. 4C is a magnified view of a portion of the fluidic-channel cooled substrate 400 indicated by the inset 4C in FIG. 4B. As shown in FIGS. 4A-4C, the fluidic-channel cooled substrate 400 includes a ceramic substrate 405, which can include silicon nitride (SiN), aluminum nitride (AlN), and/or aluminum oxide (Al₂O₃), as some examples. A patterned metal layer 410 is disposed on the ceramic substrate 405. In some implementations, such as those described herein, one or more semiconductor die, e.g., of a power semiconductor device circuit, can be disposed on, or coupled with the patterned metal layer 410. For instance, the semiconductor die can be sintered to, and/or soldered to the patterned metal layer 410.

As shown in FIGS. 4B and 4C, a fluidic-channel cooling structure 420 can be coupled with the ceramic substrate 405. In this example, the fluidic-channel cooling structure 420 can be directly coupled with the ceramic substrate 405, such as on a surface of the ceramic substrate 405 opposite the surface on which the patterned metal layer 410 is disposed. For instance, the fluidic-channel cooling structure 420 can be brazed, diffusion bonded, or sintered to the ceramic substrate 405, without use of a thermal interface material, solder, or other adhesive. Such an arrangement can be referred to as a direct-cooling arrangement, as the fluidic-channel cooling structure 420 is directly coupled with a ceramic surface of the ceramic substrate 405.

As shown in FIG. 4B, and illustrated in further detail in FIG. 4C, the fluidic-channel cooling structure 420 can include, or be formed from a plurality of layers having different structures. In some implementations, the layers of the fluidic-channel cooling structure 420 can be implemented using copper sheets that are formed using stamping, etching, casting, machining, and so forth, to achieve the desired structure of each sheet or layer. Those sheets can then be coupled together, such as using brazing, to form the fluidic-channel cooling structure 420. In some implementations, after defining features used for forming fluidic-cooling channels in sheets of the fluidic-channel cooling structure 420, those sheets (and the defined features) can be plated or coated with a corrosion-resistant material. For instance, in some implementations, sheets of the fluidic-channel cooling structure 420 can be copper sheets that, after defining fluidic-cooling channel features and before stacking and attachment of the sheets, are each plated with nickel. In other implementations, sheets used for producing the fluidic-channel cooling structure 420 can be plated prior to stacking and attachment.

As shown in FIG. 4C, in this example, the fluidic-channel cooling structure 420 includes a layer 420a, a plurality of layers 420b, a plurality of layers 420c, and a layer 420c1. In other implementations, other layers, or combinations of layers can be used.

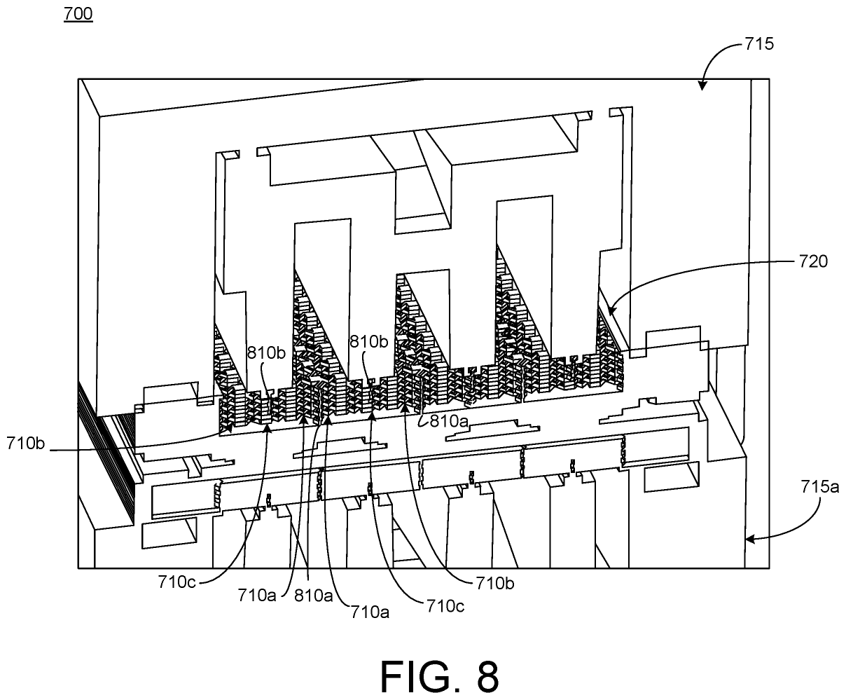

In this example, the layer 420a can be a cap layer of the fluidic-channel cooling structure 420, which is coupled with the ceramic substrate 405 and also fluidic seals the U-turn portions of the fluidic-channels. The layer 420b can be referred to U-turn layers, which can define the U-turn portions of fluidic-channels of the fluidic-channel cooling structure 420, such as the U-turn portion 310c of the fluidic-channel 310. For instance, openings, or holes formed in copper sheets (plate or un-plated) used to implement the layers 420b can define the U-turn portions. The layers 420b can also define respective first portions of barriers, or walls between respective inlet portions of adjacent fluidic-channels, respective first portion of barriers, or walls between respective outlet portions of adjacent fluidic-channels. Such barriers, or walls are shown, at least, in the example implementation illustrated in FIG. 8.

The layers 420c can be referred to as inlet/outlet layers, and can define the inlet portions and the outlet portion of fluidic-channels of the fluidic-channel cooling structure 420, such as the inlet portion 310a and the outlet portion 310b of the fluidic-channel 310. For instance, openings, or holes formed in copper sheets (plated or un-plated) used to implement the layers 420c can define the inlet portions and the outlet portions of the fluidic-channels. The layers 420c can also define respective second portions of the barriers, or walls between adjacent inlet portions and adjacent outlet portions, as well as define respective barriers, or walls between respective inlet portions and outlet portions of each fluidic channel of the fluidic-channel cooling structure 420. Again, such barriers, or walls are shown, at least, in the example implementation illustrated in FIG. 8. For purposes of this disclosure, a barrier, or wall, refers to structure that, at least locally, prohibits coolant flow in a given direction. In other words, such barriers, or walls can be configured to direct coolant flow through an inlet portion of a fluidic-channel to a U-turn portion of the fluidic-channel, and also direct coolant flow from the U-turn portion to the outlet portion of the fluidic-channel.

The layer 420cl can be referred to as a fluidic interface layer. The layer 420cl, which could be implemented using multiple layers of copper sheets that are plated or un-plated, can be configured to fluidically interface with a corresponding coolant distributor. For instance, the 420cl can be configured such that fluidic seals are formed with a coolant distributor, such as to prevent coolant flow between inlet channels and outlet channels of the coolant distributor.

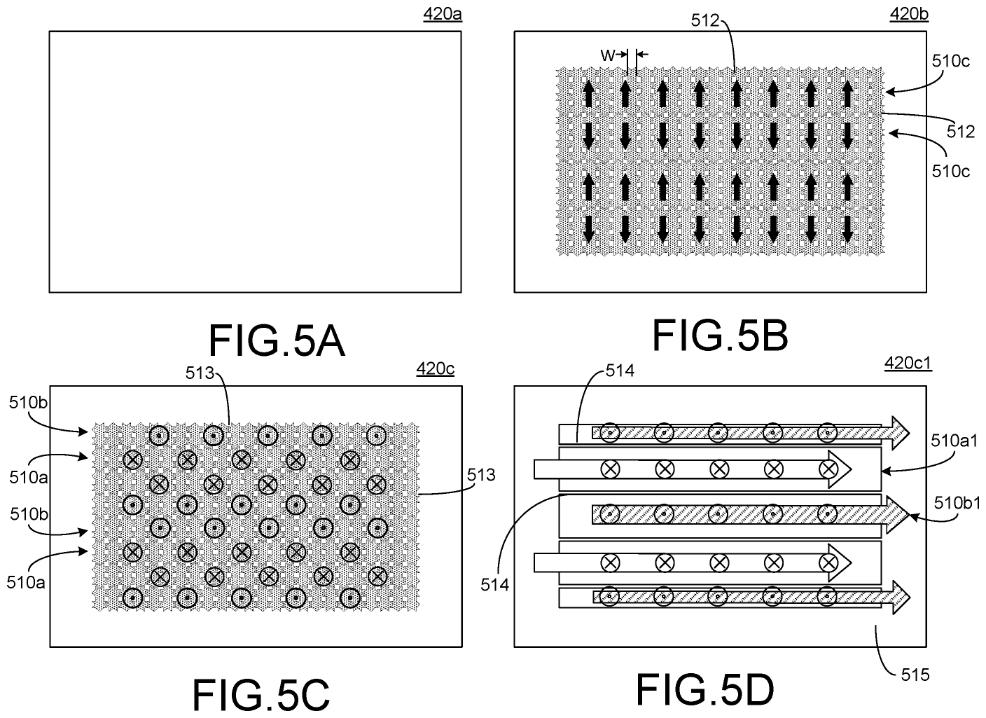

FIGS. 5A through 5D are diagrams illustrating example layers of a fluidic-channel cooling structure, such as the fluidic-channel cooling structure 420 of the fluidic-channel cooled substrate 400. Accordingly, for purposes of illustration, FIGS. 5A to 5D are described with further reference to FIGS. 4A to 4C. FIG. 5A illustrates an example of the layer 420a, which in this example can be a solid copper sheet (plated or un-plated) that is used to couple the fluidic-channel cooling structure 420 to the ceramic substrate 405, as well as to fluidically seal the fluidic-channels of the fluidic-channel cooling structure 420, specifically U-turn portions. In FIGS. 5C and 5D, circles with an X in the center indicate inlet coolant flow, while circles with a dot in the center indicate outlet coolant flow. Also, in FIGS. 5B, 5C and 5D the various sheets include references indicating inlet portions are indicated as 510a, outlet portions as 510b, and U-turn portions as 510c.

FIG. 5B illustrates an example of the layers 420b. As shown in FIG. 5B, features 512 can be defined from a copper sheet, where the features 512 define openings in the copper sheet. The copper sheets of the layers 420b can be plated or un-plated. By stacking a plurality of the layers 420b, such shown FIG. 4C, U-turn portions of fluidic-channels of the fluidic-channel cooling structure 420 can be defined, as well as the first portions of the barriers, or walls disposed between respective inlet portions of adjacent fluidic-channels, and the first portions of the barriers, or walls between respective outlet portions of adjacent fluidic-channels. Respective directions of coolant flow in corresponding U-turn portions defined by the layers 420b in this example are indicated by the arrows in FIG. 5B. As shown FIG. 5B, the fluidic-channels of the fluidic-channel cooling structure 420 can have a width W. In some implementations, the width W can be 1.0 millimeter (mm) or greater (e.g., greater than 1.1 mm, or greater than 1.2 mm). For instance, the width W can be determined based on size of particulates that can be present in cooling fluid that is circulated through the fluidic-channel cooling structure 420, e.g., a coolant fluid that is used in a given fluidic-channel cooling structure, such as those described herein.

FIG. 5C illustrates an example of the layers 420c. As shown in FIG. 5C, features 513 can be defined in a copper sheet, where the features 513 define openings in the copper sheet, which can be plated or un-plated. By stacking a plurality of the layers 420c, such as shown in FIG. 4C, inlet portions and outlet portions of the fluidic-channels of the fluidic-channel cooling structure 420 can be defined, as well as the second portions of the barriers, or walls disposed between respective inlet portions of adjacent fluidic-channels, and the second portions of the barriers, or walls between respective outlet portions of adjacent fluidic-channels. Further the features 513 can define the barriers, or walls between respective inlet portions and outlet portions of each fluidic channel of the fluidic-channel cooling structure 420.

FIG. 5D illustrates an example of the layer 420c1. As shown in FIG. 5D, features 514 can be defined in a copper sheet that can, after defining the features 514, can be plated, such as nickel plated. The features 514 can correspond to inlet channels and outlet channels of a corresponding coolant distributor 315. The layer 420c1 also include a sealing surface 515, which can be used for a fluidic seal between the layer 420c1 and the coolant distributor and/or a corresponding cooling jacket. For instance, the layer 420c1 and a corresponding coolant distributor can be configured to define fluidic seals between the coolant distributor, the sealing surface 515 and/or the features 514 of the layer 420cl. For instance, a sealing member of sealant compound, such as silicone can be used. As an example, in some implementations, a sealing member can be a rubber member, such as an O-ring. The particular sealing mechanism, or sealing mechanisms used between a fluidic-channel cooling structure, a corresponding coolant distributor, and/or a corresponding cooling jacket will depend on the particular implementation.

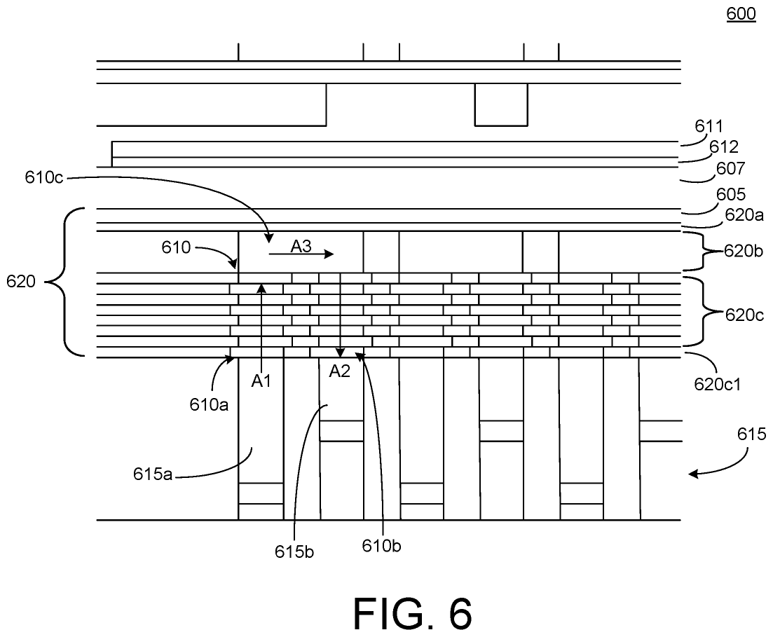

FIG. 6 is a diagram illustrating an example semiconductor device 600 including a fluidic-channel cooled substrate and a coolant distributor. As shown in the FIG. 6, the semiconductor device 600 includes a ceramic substrate 605 with a metal layer 607 disposed on a first surface of the ceramic substrate 605. The semiconductor device 600 also includes a semiconductor die 611 that is coupled with the metal layer 607 via solder layer 612. In some implementations, the semiconductor die 611 can be sintered to the metal layer 607 in place of soldering. The metal layer 607 of the semiconductor device 600 can, in some implementations, correspond with the patterned metal layer 410 of the fluidic-channel cooled substrate 400.

In this example, the semiconductor device 600 includes a fluidic-channel cooling structure 620 that includes a plurality of copper sheets, such as the examples of FIGS. 4A-4C and 5A-5D. For instance, the fluidic-channel cooling structure 620 includes a layer 620a, which can be a cap layer of the fluidic-channel cooling structure 620. The fluidic-channel cooling structure 620 further includes a layer 620b, which can define U-turn portions of the fluidic-channels of the fluidic-channel cooling structure 620, such as a U-turn portion 610c of a fluidic-channel 610. While shown as a single layer in FIG. 6, in some implementations, the layer 620a can include a plurality of layers, such the layers 420b of the fluidic-channel cooling structure 420. As also shown in the FIG. 6, the fluidic-channel cooling structure 620 also includes a plurality of layers 620c, which can define inlet portions and outlet portions of fluidic-channels of the fluidic-channel cooling structure 620, such as an inlet portion 610a of the fluidic-channel 610 and an outlet portion 610b of the fluidic-channel 610. As shown, features of the plurality of layers 620c can define openings in the layers which can form the inlet portion 610a and the outlet portion 610b of the fluidic-channel 610 when the plurality of layers 620c are stacked together. As shown in FIG. 6, the inlet portion 610a is aligned, or arranged along an axis A1 that is orthogonal to the surface of the ceramic substrate 605 to which the fluidic-channel cooling structure 620 is coupled. Likewise, the outlet portion 610b is aligned, or arranged along an axis A2 that is also orthogonal to the surface of the ceramic substrate 605 to which the fluidic-channel cooling structure 620 is coupled. The U-turn portion 610c is aligned, or arranged along an axis A3 that is parallel to the surface of the ceramic substrate 605 to which the fluidic-channel cooling structure 620 is coupled. As described herein, in some implementations, the sheets of the fluidic-channel cooling structure 620 can be plated or coated with a corrosion-resistant material, For instance, the sheets of the fluidic-channel cooling structure 620 can be nickel-plated copper.

As shown in FIG. 6, the openings in the plurality of layers 620c that form the inlet portion 610a and the outlet portion 610b can be offset from layer to layer. That is, those openings may not be vertically aligned with one another. Such an arrangement can be beneficial, as it can cause a turbulent coolant flow in the fluidic-channel 610, which can improve thermal transfer efficiency of the fluidic-channel cooling structure 620, as compared with using a non-turbulent coolant flow. The fluidic-channel cooling structure 620 further includes a layer 620c1, which can correspond with the layer 420cl of the fluidic-channel cooling structure 420, such as shown in FIG. 5D. As further shown in FIG. 6, in this example, coolant can be supplied to the inlet portion 610a of the fluidic-channel 610 from a inlet channel 615a of a coolant distributor 615, while coolant can egress from the outlet portion 610b of the fluidic-channel cooling structure 620 to an outlet channel 615b of the coolant distributor 615.

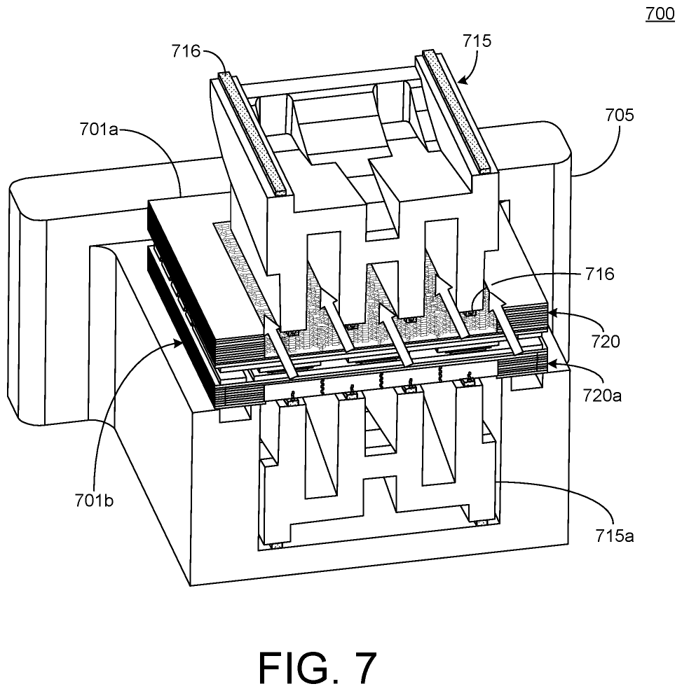

FIG. 7 is a diagram illustrating a cut-way view of an example electronic device assembly 700 including dual-sided fluidic-channel cooled substrates, coolant distributors, and a fluidic coolant jacket. For instance, the electronic device assembly 700 includes a fluidic-channel cooled substrate 701a and a fluidic-channel cooled substrate 701b. The fluidic-channel cooled substrate 701a includes a fluidic-channel cooling structure 720, while the fluidic-channel cooled substrate 701b includes a fluidic-channel cooling structure 720a. In this example, the fluidic-channel cooled substrate 701a can be coupled with respective first primary surfaces of one more semiconductor die (not specifically referenced in FIG. 7), while the fluidic-channel cooled substrate 701b is coupled with second primary surfaces of the semiconductor die.

In the example of FIG. 7, a coolant distributor 715 is coupled with the fluidic-channel cooling structure 720, such as with the layer 620c1, while a coolant distributor 715a is similarly coupled with the fluidic-channel cooling structure 720a. In order to illustrate the arrangements of the elements of the electronic device assembly 700, the electronic device assembly 700 is, as indicated above, illustrated without molding compound and with portions of the electronic device assembly 700 cut away. For instance, the fluidic-channel cooled substrate 701a and the fluidic-channel cooled substrate 701b are illustrated without corresponding molding compound. Furthermore, the electronic device assembly 700 is illustrated with portions of the fluidic-channel cooled substrate 701a, the fluidic-channel cooled substrate 701b, the coolant distributor 715, and the coolant distributor 715a are cut away. Also shown in FIG. 7 is a cooling jacket 705, which is illustrated with portions cut away.

As shown in FIG. 7, in this example, the coolant distributor 715a, the fluidic-channel cooled substrate 701b, the fluidic-channel cooled substrate 701a, and the coolant distributor 715 can be fluidically sealed in the cooling jacket 705, such that coolant flow in the cooling jacket 705 is routed, by the coolant distributor 715 and the coolant distributor 715a, through the fluidic-channel cooling structure 720 and the fluidic-channel cooling structure 720a. That is, the electronic device assembly 700 can be configured such that coolant flow in the cooling jacket 705 does not bypass the coolant distributor 715, the fluidic-channel cooled substrate 701a, the fluidic-channel cooled substrate 701b, and the coolant distributor 715a. For instance, sealing members 716 can be used to provide such fluidic seals between elements of the electronic device assembly 700. The coolant distributor 715, the coolant distributor 715a, the fluidic-channel cooled substrate 701a, and/or the fluidic-channel cooled substrate 701b can have grooves defined therein, where the grooves are configured to receive the members 716, or other sealing mechanisms, such as silicone sealant. Sealing surfaces of the fluidic-channel cooling structure 720 and the fluidic-channel cooling structure 720a can be sealed to the cooling jacket 705 and/or to, respectively, the coolant distributor 715 or the coolant distributor 715a.

FIG. 8 is a diagram illustrating a magnified view of a portion of the electronic device assembly 700 of FIG. 7. Accordingly, the specific details discussed above with respect to FIG. 7 are not repeated again here with respect to FIG. 8. For purposes of comparison with FIG. 7, FIG. 8 includes 700 series reference numbers corresponding to those of FIG. 7 for corresponding elements. In FIG. 8, inlet portions 710a, outlet portions 710b, and U-turn portions 710c for example adjacent fluidic-channels of the fluidic-channel cooling structure 720 are shown. FIG. 8 also illustrates walls, or barriers 810a that are disposed to between inlet portions 710a of adjacent fluidic channels of the fluidic-channel cooling structure 720, or are disposed between outlet portions 710b of adjacent fluidic channels of the fluidic-channel cooling structure 720. As described herein, the barriers 810a can be defined by features of U-turn layers of the fluidic-channel cooling structure 720 (e.g., layers 420b or 620b) and by features of inlet/outlet layers of the fluidic-channel cooling structure 720 (e.g., the plurality of layers 620c or the layers 420c). Also shown in FIG. 8 are walls 810b that are disposed between the inlet portions 710a and the outlet portions 710b the fluidic channels of the fluidic-channel cooling structure 720. As described herein, the walls 810b can be defined by features of the U-turn layers of the fluidic-channel cooling structure 720.

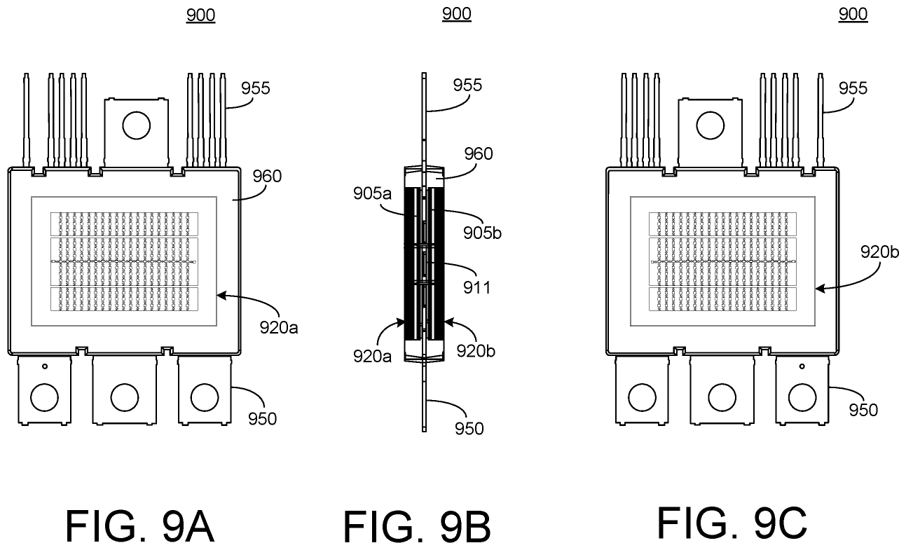

FIGS. 9A through 9C are diagrams illustrating an example molded power module 900 with dual-sided, fluidic-channel cooling. As shown in FIGS. 9A to 9C, the molded power module 900 includes a plurality of power terminals or power tabs 950. In some implementations, the power tabs 950 can be power supply terminals, or can be output signals of the molded power module 900, such as a switching node output of a half-bridge circuit. The molded power module 900 further includes signal pins 955, which can be used for control signals and/or monitoring signals of the molded power module 900, such as gate signals, source sense signals for transistors included in the molded power module 900, and/or thermal sense signals, as some examples.

The molded power module 900 also includes a molding compound 960 that encapsulates a ceramic substrate 905a, a ceramic substrate 905b, and semiconductor die 911. As shown in FIG. 9B, where the molding compound 960 is illustrated as being transparent, the ceramic substrate 905a, for example, a patterned metal layer of the ceramic substrate 905a, is coupled with respective first primary surfaces of the semiconductor die 911. Likewise, the ceramic substrate 905b, for example, a patterned metal layer of the ceramic substrate 905b, is coupled with second respective and opposite primary surfaces of the semiconductor die 911.

As also shown in FIG. 9B, a fluidic-channel cooling structure 920a is coupled with the ceramic substrate 905a on a surface opposite the semiconductor die 911. Further, a fluidic-channel cooling structure 920b is coupled with the ceramic substrate 905a on a surface opposite the semiconductor die 911. As described herein, the fluidic-channel cooling structure 920a and the fluidic-channel cooling structure 920b can be directly coupled, respectively, with the ceramic substrate 905a and the ceramic substrate 905b, for example by brazing or sintering. That is, there may be no thermal interface material, solder or other adhesive material disposed between the fluidic-channel cooling structure 920a and the fluidic-channel cooling structure 920b and their respective ceramic substrates.

As shown in FIG. 9A, a fluidic interface surface of the fluidic-channel cooling structure 920a can be exposed through the molding compound 960 on a first side, or surface of the molding compound 960, while the fluidic-channel cooling structure 920b can be exposed through the molding compound 960 on a second side, or surface of the molding compound 960 opposite the first surface. In some implementations, the fluidic interface surfaces of the fluidic-channel cooling structure 920a and the fluidic-channel cooling structure 920b can be configured to be fluidically coupled with a respective coolant distributor, such as in the examples described herein.

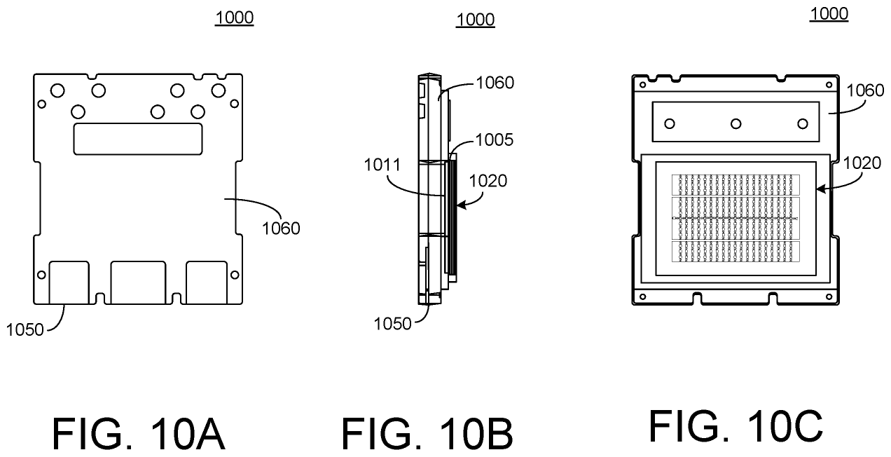

FIGS. 10A through 10C are diagrams illustrating an example molded power module 1000 with single-sided, fluidic-channel cooling. As shown in FIGS. 10A to 10C, the molded power module 1000 includes a plurality of power terminals or power tabs 1050. The power tabs 1050 can be power supply terminals, or can be output signals of the molded power module 1000, such as a switching node output of a half-bridge circuit. While not specifically shown in FIGS. 10A to 10C, in some implementations, the molded power module 1000 can further include signal pins, such as the signal pins 955 of the molded power module 900.

The molded power module 1000 also includes a molding compound 1060 that encapsulates a ceramic substrate 1005 and semiconductor die 1011. As shown in FIG. 10B, where the molding compound 1060 is illustrated as being transparent, the ceramic substrate 1005, for example, a patterned metal layer of the ceramic substrate 1005, is coupled with the semiconductor die 1011.

As also shown in FIG. 10B, a fluidic-channel cooling structure 1020 is coupled with the ceramic substrate 1005 on a surface opposite the semiconductor die 1011. As described herein, the fluidic-channel cooling structure 1020 can be directly coupled with the ceramic substrate 1005, for example by brazing or sintering. That is, there may be no thermal interface material, solder or other adhesive material disposed between the fluidic-channel cooling structure 1020 the ceramic substrate 1005.

As shown in FIG. 10A, the power tabs 1050 are exposed through the molding compound 1060 on a first side the molding compound 1060. As shown in FIG. 10C, a fluidic interface surface of the fluidic-channel cooling structure 1020 is exposed through the molding compound 1060 on a second side, or surface of the molding compound 1060 opposite the first surface. In some implementations, the fluidic interface surface of the fluidic-channel cooling structure 1020 can be configured to be fluidically coupled with a corresponding coolant distributor, such as in the examples described herein.

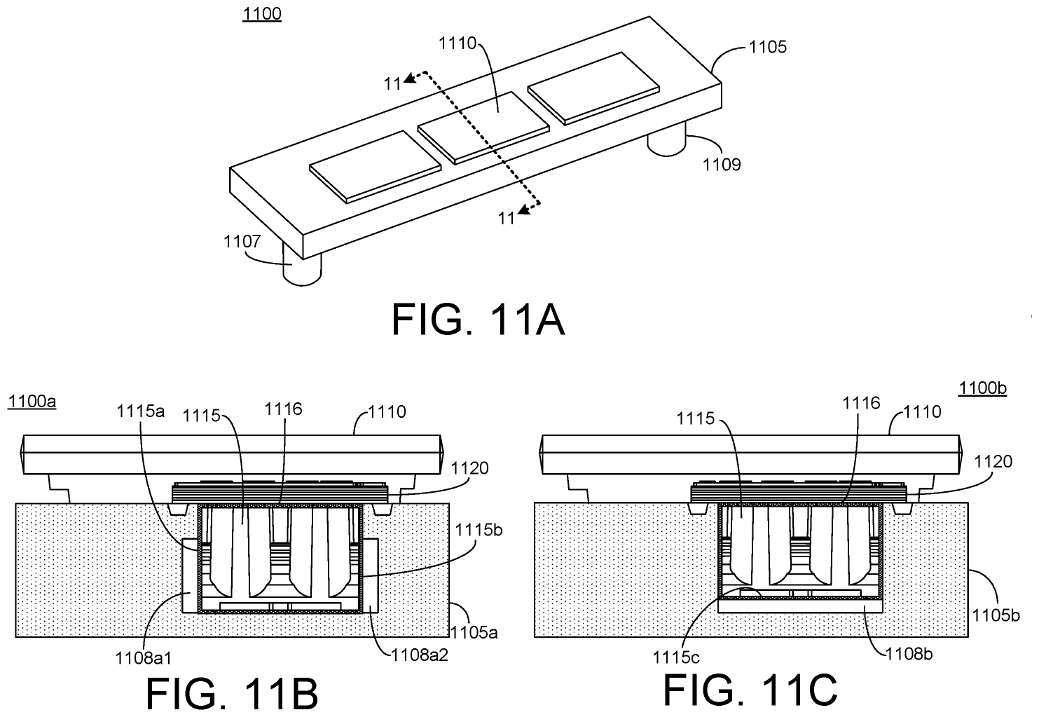

FIG. 11A is a diagram illustrating an example electronic device assembly 1100. As shown in FIG. 11A, the electronic device assembly 1100 includes a power module 1110 (e.g., a plurality of power modules), which is/are coupled with and/or disposed on a fluidic cooling jacket 1105. The fluidic cooling jacket 1105 of FIG. 11A includes an inlet 1107 (inlet port, fluid inlet, coolant inlet, etc.) that is configured to receive a coolant flow for the electronic device assembly 1100. In some implementations, the power module 1110 can include a cooling structure, such as the fluidic-channel cooling structures described herein. Further, the electronic device assembly 1100 can include a respective coolant distributor (not visible in FIG. 11A) for each power module 1110. For instance, a coolant distributor, such as those described herein, can be disposed in the fluidic cooling jacket 1105 and fluidically sealed with a cooling structure of a corresponding power module 1110 of the electronic device assembly 1100.

The fluidic cooling jacket 1105 also includes an outlet 1109 (outlet port, fluid outlet, coolant outlet, etc.) that is configured to egress the coolant flow received at the inlet 1107 from the fluidic cooling jacket 1105 of the electronic device assembly 1100. For instance, a coolant flow can egress the fluidic cooling jacket 1105 from the outlet 1109 after flowing through the fluidic cooling jacket 1105, and/or through respective cooling structures and coolant distributors for each power module 1110 of the electronic device assembly 1100.

FIGS. 11B and 11C are diagrams schematically illustrating cross-sectional views of example implementations of the electronic device assembly of FIG. 11A, respectively, electronic device assembly 1100a and electronic device assembly 1100b. In these examples, the cross-sectional view of the electronic device assembly 1100a (FIG. 11B) and the cross-sectional view of the electronic device assembly 1100b (FIG. 11C) are example views along the section line 11-11 in FIG. 11A.

As shown in FIG. 11B, the electronic device assembly 1100a includes the power module 1110, which is disposed on (fluidically sealed with) a fluidic cooling jacket 1105a. For instance, in this example, a fluidic-channel cooling structure 1120 of the power module 1110 is fluidically sealed with a coolant distributor 1115 of the electronic device assembly 1100a. In this example, a fluidic seal between the fluidic-channel cooling structure 1120 and the coolant distributor 1115 is formed by a sealing member 1116, which can be sealing member such as those described herein, e.g., an O-ring, a compliant rubber material, a silicone member, and so forth. Also in this example, the sealing member 1116 further fluidically seals a bottom of the coolant distributor 1115 with an interior surface of the fluidic cooling jacket 1105a.

As also shown in FIG. 11B, the fluidic cooling jacket 1105a includes a fluidic bypass channel 1108a1 that is disposed along a sidewall 1115a of the coolant distributor 1115, and a fluidic bypass channel 1108a2 that is disposed along a sidewall 1115b of the coolant distributor 1115. In this example, the sidewall 1115a and the sidewall 1115b are both orthogonal to a fluidic interface surface of the fluidic-channel cooling structure 1120 and opposite one another in the coolant distributor 1115. In this example, a flow of coolant in the fluidic cooling jacket 1105a can be divided between the coolant distributor 1115, the fluidic bypass channel 1108a1, and the fluidic bypass channel 1108a2. That is, in the example of FIG. 11B, a first portion of the coolant flow received at the inlet 1107 can flow through the fluidic bypass channel 1108a1, a second portion of the coolant flow can flow through the coolant distributor 1115 and the fluidic-channel cooling structure 1120, and a third portion of the coolant flow can flow through the fluidic bypass channel 1108a2.

In this example, the fluidic bypass channel 1108a1 and/or the fluidic bypass channel 1108a2 can be sized, e.g., relative to the coolant distributor 1115, to regulate a coolant flow pressure differential between the inlet 1107 and the outlet 1109 of the fluidic cooling jacket 1105a. For instance, in some implementations, increasing a relative size of the fluidic bypass channel 1108a1 and/or a relative size of the fluidic bypass channel 1108a2 can reduce such a pressure differential, while decreasing a relative size of the fluidic bypass channel 1108a1 and/or a relative size of the fluidic bypass channel 1108a2 can increase such a pressure differential. That is, by changing a portion of a coolant flow that flows in the fluidic bypass channel 1108a1 and/or the fluidic bypass channel 1108a2, relative to a portion of coolant flow that flows in the coolant distributor 1115 and the fluidic-channel cooling structure 1120 of each power module 1110 of the electronic device assembly 1100 can regulate (vary, change, tune, etc.) a differential between a fluid pressure at the inlet 1107 and a corresponding fluid pressure at the outlet 1109, which can improve thermal dissipation efficiency for the electronic device assembly 1100 in operation.

As shown in FIG. 11C, the electronic device assembly 1100b includes the power module 1110, which is disposed on (fluidically sealed with) a fluidic cooling jacket 1105b. For instance, in this example, a fluidic-channel cooling structure 1120 of the power module 1110 is fluidically sealed with a coolant distributor 1115 of the electronic device assembly 1100b. In this example, the fluidic seal between the fluidic-channel cooling structure 1120 and the coolant distributor 1115 is formed by a sealing member 1116, which can be sealing member such as those described herein, e.g., an O-ring, a compliant rubber material, a silicone member, and so forth. Also in this example, the sealing member 1116 further fluidically seals sides of the coolant distributor 1115 with respective interior surfaces of the fluidic cooling jacket 1105b.

As also shown in FIG. 11C, the fluidic cooling jacket 1105b includes a fluidic bypass channel 1108b that is disposed along a bottom wall 1115c of the coolant distributor 1115. In this example, the bottom wall 1115c is parallel to the fluidic interface surface of the fluidic-channel cooling structure 1120 of the power module 1110. Further in this example, a flow of coolant in the fluidic cooling jacket 1105b can be divided between the coolant distributor 1115, and the fluidic bypass channel 1108b. That is, in the example of FIG. 11C, a first portion of the coolant flow received at the inlet 1107 can flow through the fluidic bypass channel 1108b, and a second portion of the coolant flow can flow through the coolant distributor 1115 and the fluidic-channel cooling structure 1120.

In this example, the fluidic bypass channel 1108b, as with the fluidic bypass channel 1108a1 and the fluidic bypass channel 1108a2 of FIG. 11B, can be sized, e.g., relative to the coolant distributor 1115, to regulate a coolant flow pressure differential between the inlet 1107 and the outlet 1109 of the fluidic cooling jacket 1105b. For instance, in some implementations, increasing a relative size of the fluidic bypass channel 1108b can reduce such a pressure differential, while decreasing a relative size of the fluidic bypass channel 1108b can increase such a pressure differential. That is, by changing a portion of a coolant flow that flows in the fluidic bypass channel 1108b relative to a portion of coolant flow that flows in the coolant distributor 1115 and the fluidic-channel cooling structure 1120 of each power module 1110 of the electronic device assembly 1100 can regulate (vary, change, tune, etc.) a differential between a fluid pressure at the inlet 1107 and a corresponding fluid pressure at the outlet 1109, which can improve thermal dissipation efficiency of such implementations.

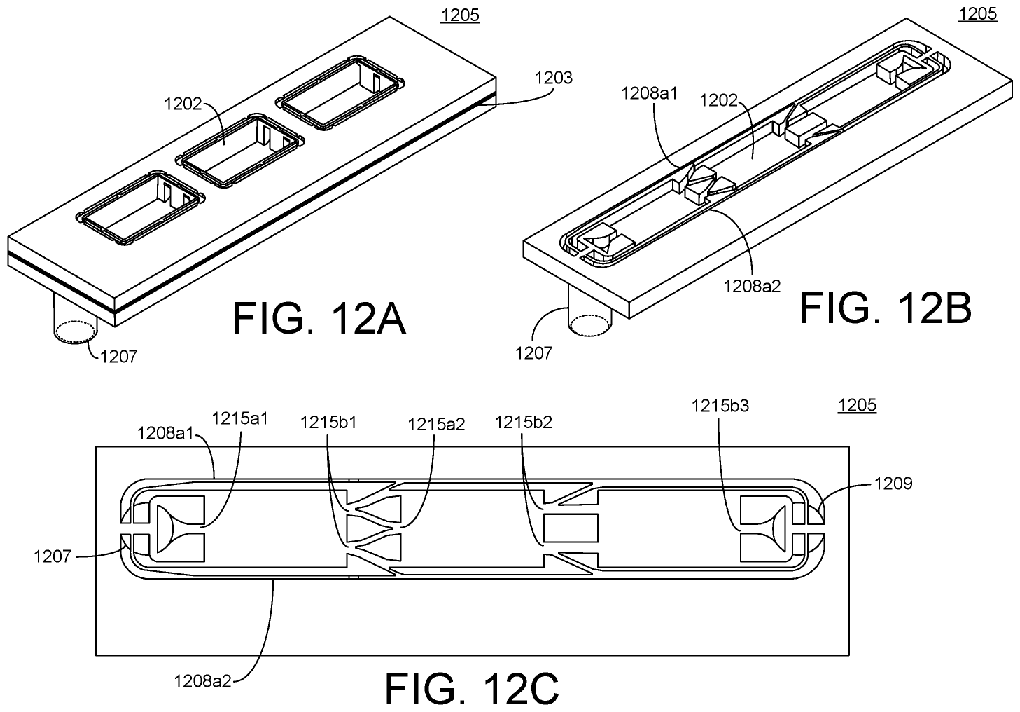

FIGS. 12A through 12C are diagrams illustrating an example fluidic cooling jacket 1205, which can be an implementation of the fluidic cooling jacket 1105a of FIG. 11B. FIG. 12A is a diagram illustrating an isometric view of the fluidic cooling jacket 1205. As shown in FIG. 12A, the fluidic cooling jacket 1205 includes an inlet 1207, which can be a coolant fluid inlet, such as described herein. While not visible in the view of FIG. 12A, the fluidic cooling jacket 1205 can also include an outlet, which can be used for egress of coolant from the fluidic cooling jacket 1205. In this example, the fluidic cooling jacket 1205 further includes an opening 1202 (recess, cavity, etc.). In this example, the fluidic cooling jacket 1205 of FIG. 12A includes three such openings. The opening 1202 can be configured to receive a coolant distributor, which can be fluidically sealed in the opening 1202, and disposed within the fluidic cooling jacket 1205. Also shown in FIG. 12A, is a section line 1203, which corresponds with the cross-sectional views of the fluidic cooling jacket 1205 shown in FIGS. 12B and 12C.

FIG. 12B is a diagram illustrating an isometric view of the fluidic cooling jacket 1205 after sectioning along the section line 1203, while FIG. 12C is a diagram of a top down layout view of the fluidic cooling jacket 1205 after sectioning along the section line 1203. As can be seen in FIGS. 12B and 12C, the fluidic cooling jacket 1205 includes a fluidic bypass channel 1208a1 and a fluidic bypass channel 1208a2. The fluidic cooling jacket 1205 further includes coolant distributor inlet channels, such as inlet channels 1215a1 and 1215a2, and coolant distributor outlet channels, such as outlet channels 1215b1, 1215b2 and 1215b3 In this example, a coolant flow can be provided via the inlet 1207. A first portion of the coolant flow from the inlet 1207 can flow in the fluidic bypass channel 1208a1, a second portion of the coolant flow from the inlet 1207 can flow in the fluidic bypass channel 1208a2, and a third portion of the coolant flow from the inlet 1207 can flow in the inlet channel 1215a1.

As shown in FIGS. 12B and 12C, at each of the coolant distributor coolant outlet channels (e.g., 1215b1 and 1215b2), coolant can flow from, or to the fluidic bypass channel 1208a1 and/or the fluidic bypass channel 1208a2. That is, respective amounts of coolant flowing through coolant distributors included in the fluidic cooling jacket 1205 and in the fluidic bypass channels 1208a1 1208a2 can change. As also shown in FIG. 12C, coolant flow from the outlet channel 1251b2, the fluidic bypass channel 1208a1, and the fluidic bypass channel 1208a2 can egress the fluidic cooling jacket 1205 via an outlet 1209. The various fluidic channels in the fluidic cooling jacket 1205 can be sized, e.g., as described herein, to adjust a coolant flow pressure differential between the inlet 1207 and the outlet 1209.

In a general aspect, a semiconductor device module includes a ceramic substrate having a first surface and a second surface opposite the first surface, a patterned metal layer disposed on the first surface of the ceramic substrate, a semiconductor die disposed on the patterned metal layer, and a cooling structure disposed on the second surface of the ceramic substrate. The cooling structure includes a plurality of copper sheets defining a plurality of fluidic-cooling channels. At least one copper sheet of the plurality of copper sheets is at least one of coated or plated with a corrosion-resistant material. The module also includes a molding compound that encapsulates the ceramic substrate, the patterned metal layer and the semiconductor die. The molding compound also partially encapsulates the cooling structure, such that a fluidic interface surface of the cooling structure is exposed through the molding compound.

Implementations can include one or more of the following features, alone or in combination. For example, the plurality of fluidic-cooling channels can be configured to be in fluidic communication with a coolant distributor.

A fluidic-cooling channel of the plurality of fluidic-cooling channels can have a width of greater than 1.0 millimeter.

A fluidic-cooling channel of the plurality of fluidic-cooling channels can include an inlet portion, an outlet portion, and a U-turn portion. The U-turn portion can fluidically couple the inlet portion with the outlet portion. The inlet portion can be arranged along a first axis and the outlet portion can be arranged along a second axis. The first axis and the second axis can be orthogonal to the second surface of the ceramic substrate. The U-turn portion can be arranged along a third axis that is parallel to the second surface of the ceramic substrate. The inlet portion and the outlet portion can be defined by a first subset of the plurality of copper sheets. The U-turn portion can be defined by a second subset of the plurality of copper sheets.

The fluidic-cooling channel can be a first fluidic-cooling channel. The first subset of the plurality of copper sheets can define a barrier between the inlet portion and the outlet portion of the first fluidic-cooling channel, and a first portion of a barrier between the inlet portion of the first fluidic-cooling channel and an inlet portion of a second fluidic-cooling channel. The second subset of the plurality of copper sheets can define a second portion of the barrier between the inlet portion of the first fluidic-cooling channel and the inlet portion of the second fluidic-cooling channel.

The inlet portion of the first fluidic-cooling channel can be adjacent to the inlet portion of the second fluidic-cooling channel.

The first subset of the plurality of copper sheets can define a first portion of a barrier between the outlet portion of the first fluidic-cooling channel and an outlet portion of a second fluidic-cooling channel. The second subset of the plurality of copper sheets can define a second portion of the barrier between the outlet portion of the first fluidic-cooling channel and the outlet portion of the second fluidic-cooling channel.

The outlet portion of the first fluidic-cooling channel can be adjacent to the outlet portion of the second fluidic-cooling channel.

In another general aspect, an electronic device assembly includes a molded semiconductor device module. The assembly includes a ceramic substrate having a first surface and a second surface opposite the first surface, a patterned metal layer disposed on the first surface of the ceramic substrate, a semiconductor die disposed on the patterned metal layer, and a cooling structure disposed on the second surface of the ceramic substrate. The cooling structure includes a plurality of fluidic-cooling channels, and a molding compound. The molding compound encapsulates the ceramic substrate, the patterned metal layer and the semiconductor die. The molding compound also partially encapsulates the cooling structure, such that a fluidic interface surface of the cooling structure is exposed through the molding compound. The assembly also includes a coolant distributor coupled with the fluidic interface surface of the cooling structure, and a fluidic-cooling jacket. The fluidic-cooling jacket includes a coolant inlet, a first fluidic circuit configured to provide a first portion of a coolant flow received at the coolant inlet to the coolant distributor, a second fluidic circuit configured such that a second portion of the coolant flow bypasses the coolant distributor, and a coolant outlet configured to receive the first portion of the coolant flow and the second portion of the coolant flow for egress from the fluidic-cooling jacket.

Implementations can include one or more of the following features, alone or in combination. For example, the plurality of fluidic-cooling channels can include respective inlet portions, respective outlet portions, and respective U-turn portions. The respective U-turn portions can fluidically couple the respective inlet portions with the respective outlet portions. The coolant distributor can include at least one coolant-inlet channel configured to receive and provide the first portion of the coolant flow to the respective inlet portions, and at least one coolant-outlet channel configured to receive the first portion of the coolant flow from the respective outlet portions.

A coolant-inlet channel of the at least one coolant-inlet channel can include a ramped portion having a first slope. A coolant-outlet channel of the at least one coolant-outlet channel can include a ramped portion having a second slope opposite the first slope.

A coolant-inlet channel of the at least one coolant-inlet channel can include a fluidic-ingress port that is disposed on a first side of the coolant distributor. A coolant-outlet channel of the at least one coolant-outlet channel can include a fluidic-egress port that is disposed on a second side of the coolant distributor opposite the first side.

The second fluidic circuit can include a first bypass channel disposed along a first sidewall of the coolant distributor. The first sidewall can be orthogonal to the fluidic interface surface of the cooling structure, and a second bypass channel disposed along a second sidewall of the coolant distributor. The second sidewall can be opposite the first sidewall and orthogonal to the fluidic interface surface of the cooling structure.

The second fluidic circuit can include a bypass channel disposed on a bottom wall of the coolant distributor. The bottom wall can be parallel to the fluidic interface surface of the cooling structure.

An interface between the fluidic interface surface of the cooling structure and the coolant distributor can include a sealing member.

An interface between the coolant distributor and the fluidic-cooling jacket can include a sealing member.

The cooling structure can include a plurality of copper sheets defining a plurality of fluidic-cooling channels. At least one copper sheet of the plurality of copper sheets can be at least one of coated or plated with a corrosion-resistant material. The corrosion-resistant material can include nickel.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device module comprising:
a ceramic substrate having a first surface and a second surface opposite the first surface;
a patterned metal layer disposed on the first surface of the ceramic substrate;
a semiconductor die disposed on the patterned metal layer;
a cooling structure disposed on the second surface of the ceramic substrate, the cooling structure including a plurality of copper sheets defining a plurality of fluidic-cooling channels, at least one copper sheet of the plurality of copper sheets being at least one of coated or plated with a corrosion-resistant material; and
a molding compound that:
encapsulates the ceramic substrate, the patterned metal layer and the semiconductor die; and
partially encapsulates the cooling structure, such that a fluidic interface surface of the cooling structure is exposed through the molding compound.

2. The semiconductor device module of claim 1, wherein the plurality of fluidic-cooling channels are configured to be in fluidic communication with a coolant distributor.

3. The semiconductor device module of claim 1, wherein a fluidic-cooling channel of the plurality of fluidic-cooling channels has a width of greater than 1.0 millimeter.

4. The semiconductor device module of claim 1, wherein a fluidic-cooling channel of the plurality of fluidic-cooling channels includes:
an inlet portion;
an outlet portion; and
a U-turn portion that fluidically couples the inlet portion with the outlet portion.

5. The semiconductor device module of claim 4, wherein:
the inlet portion is arranged along a first axis and the outlet portion is arranged along a second axis, the first axis and the second axis being orthogonal to the second surface of the ceramic substrate; and
the U-turn portion is arranged along a third axis that is parallel to the second surface of the ceramic substrate.

6. The semiconductor device module of claim 4, wherein:
the inlet portion and the outlet portion are defined by a first subset of the plurality of copper sheets; and
the U-turn portion is defined by a second subset of the plurality of copper sheets.

7. The semiconductor device module of claim 6, wherein:
the fluidic-cooling channel is a first fluidic-cooling channel;
the first subset of the plurality of copper sheets further defines:
a barrier between the inlet portion and the outlet portion of the first fluidic-cooling channel; and
a first portion of a barrier between the inlet portion of the first fluidic-cooling channel and an inlet portion of a second fluidic-cooling channel; and
the second subset of the plurality of copper sheets further defines a second portion of the barrier between the inlet portion of the first fluidic-cooling channel and the inlet portion of the second fluidic-cooling channel.

8. The semiconductor device module of claim 7, wherein the inlet portion of the first fluidic-cooling channel is adjacent to the inlet portion of the second fluidic-cooling channel.

9. The semiconductor device module of claim 7, wherein:
the first subset of the plurality of copper sheets further defines a first portion of a barrier between the outlet portion of the first fluidic-cooling channel and an outlet portion of a second fluidic-cooling channel; and
the second subset of the plurality of copper sheets further defines a second portion of the barrier between the outlet portion of the first fluidic-cooling channel and the outlet portion of the second fluidic-cooling channel.

10. The semiconductor device module of claim 9, wherein the outlet portion of the first fluidic-cooling channel is adjacent to the outlet portion of the second fluidic-cooling channel.

11. An electronic device assembly comprising:
a molded semiconductor device module including:
a ceramic substrate having a first surface and a second surface opposite the first surface;
a patterned metal layer disposed on the first surface of the ceramic substrate;
a semiconductor die disposed on the patterned metal layer;
a cooling structure disposed on the second surface of the ceramic substrate, the cooling structure including a plurality of fluidic-cooling channels; and
a molding compound that:
encapsulates the ceramic substrate, the patterned metal layer and the semiconductor die; and
partially encapsulates the cooling structure, such that a fluidic interface surface of the cooling structure is exposed through the molding compound;
a coolant distributor coupled with the fluidic interface surface of the cooling structure; and
a fluidic-cooling jacket having:
a coolant inlet;
a first fluidic circuit configured to provide a first portion of a coolant flow received at the coolant inlet to the coolant distributor;
a second fluidic circuit configured such that a second portion of the coolant flow bypasses the coolant distributor; and
a coolant outlet configured to receive the first portion of the coolant flow and the second portion of the coolant flow for egress from the fluidic-cooling jacket.

12. The electronic device assembly of claim 11, wherein:
the plurality of fluidic-cooling channels include respective inlet portions, respective outlet portions, and respective U-turn portions, the respective U-turn portions fluidically coupling the respective inlet portions with the respective outlet portions; and
the coolant distributor including:
at least one coolant-inlet channel configured to receive and provide the first portion of the coolant flow to the respective inlet portions; and
at least one coolant-outlet channel configured to receive the first portion of the coolant flow from the respective outlet portions.

13. The electronic device assembly of claim 12, wherein:
a coolant-inlet channel of the at least one coolant-inlet channel includes a ramped portion having a first slope; and
a coolant-outlet channel of the at least one coolant-outlet channel includes a ramped portion having a second slope opposite the first slope.

14. The electronic device assembly of claim 12, wherein:
a coolant-inlet channel of the at least one coolant-inlet channel includes a fluidic-ingress port that is disposed on a first side of the coolant distributor; and
a coolant-outlet channel of the at least one coolant-outlet channel includes a fluidic-egress port that is disposed on a second side of the coolant distributor opposite the first side.

15. The electronic device assembly of claim 11, wherein the second fluidic circuit includes:
a first bypass channel disposed along a first sidewall of the coolant distributor, the first sidewall being orthogonal to the fluidic interface surface of the cooling structure; and
a second bypass channel disposed along a second sidewall of the coolant distributor, the second sidewall being opposite the first sidewall and orthogonal to the fluidic interface surface of the cooling structure.

16. The electronic device assembly of claim 15, wherein the second fluidic circuit includes a bypass channel disposed on a bottom wall of the coolant distributor, the bottom wall being parallel to the fluidic interface surface of the cooling structure.

17. The electronic device assembly of claim 15, wherein an interface between the fluidic interface surface of the cooling structure and the coolant distributor includes a sealing member.

18. The electronic device assembly of claim 15, wherein an interface between the coolant distributor and the fluidic-cooling jacket includes a sealing member.

19. The electronic device assembly of claim 15, wherein the cooling structure includes a plurality of copper sheets defining a plurality of fluidic-cooling channels, at least one copper sheet of the plurality of copper sheets being at least one of coated or plated with a corrosion-resistant material.

20. The electronic device assembly of claim 19, wherein the corrosion-resistant material includes nickel.
